(19) United States
(12) Patent Application Publication
(10) Pub. No.: US 2011/0240996 A1
(43) Pub. Date: Oct. 6, 2011

(54) OPTOELECTRONIC DEVICE AND METHOD FOR PRODUCING THE SAME

(75) Inventors: CHING-FUH LIN, Taipei (TW); JING-SHUN HUANG, Taipei (TW); JIAN-LIN CHIU, Taipei (TW)

(73) Assignee: NATIONAL TAIWAN UNIVERSITY, Taipei (TW)

(21) Appl. No.: 13/160,450

(22) Filed: Jun. 14, 2011

Related U.S. Application Data
(63) Continuation-in-part of application No. 12/726,202, filed on Mar. 17, 2010.

(30) Foreign Application Priority Data
Mar. 25, 2011 (TW) 100110260

(51) Int. Cl. H01L 31/0224; H01L 29/12; H01L 33/02; H01L 31/0264; H01L 51/44; H01L 33/62

(52) U.S. Cl. 257/43; 438/46; 438/85; 257/E29.068; 257/E33.013; 257/E31.004; 257/E33.064

(57) ABSTRACT

Embodiments of this invention disclose optoelectronic devices and their producing methods. The embodiments employ solution processes to produce p-type transition metal oxide layer, active layer, and n-type transition metal oxide layer of the optoelectronic devices. The p-type transition metal oxide layer comprises a copper oxide (CuO) layer or a nickel oxide (NiO) layer or a mixing layer, which comprises CuO or NiO mixed with an n-type transition metal oxide.

### CROSS-REFERENCE TO RELATED APPLICATIONS

This application is a continuation-in-part of co-pending U.S. application Ser. No. 12/726,202 (Att. Docket NU8368P), filed on Mar. 17, 2010 and entitled “Optoelectronic Device Having a Sandwich Structure and Method for Forming the Same” and claims priority to Taiwan Patent Application No. 100110260, filed on Mar. 25, 2011, the entire contents both of which are incorporated herein by reference, U.S. application Ser. No. 12/726,202 claims priority to Taiwan Patent Application No. 098140465, filed on Nov. 27, 2009, the entire contents of which are incorporated herein by reference.

### BACKGROUND OF THE INVENTION

1. Field of the Invention

The present invention generally relates to optoelectronic devices and their forming methods.

2. Description of Related Art

Recently, organic optoelectronic devices, such as organic solar cells (OSC), organic light emitting diodes (OLED), organic light sensors, and so on, become increasingly advantageous according to the degree produced in light-weight, small-thickness, large-area, flexible, low-cost, and environmental protection forms.

In another aspect, because moisture may damage materials of the organic optoelectronic devices and thus decrease the lifetime, manufacturers promote the packaging level of the devices and thus inevitability increase the cost. There hence remains a need to provide organic optoelectronic devices with better efficiency, longer lifetime, higher reliability, and lower cost.

For solar cells, bulk heterojunction is usually employed to promote the power conversion efficiency (PCE) by means of increased interface area between the donor and acceptor, resulting in more excitons reaching the interface and then separating into electron-hole pairs.

In order to augment the power conversion efficiency of organic optoelectronic devices, a buffer layer may be interposed between the organic layer and the transparent electrode. For example, a thin layer composed of calcium or lithium fluoride may be disposed between the aluminum electrode and the organic layer. A buffer layer including, for instance, poly(3,4-ethylenedioxythiophene), or PEDOT, may be disposed between the transparent electrode and the organic layer to increase the power conversion efficiency.

However, an aluminum electrode, or a buffer layer of calcium or lithium fluoride, is susceptible to being oxidized in the presence of air, causing the resistance of the device to increase. On the other hand, a buffer layer of PEDOT may over time result in corrosion of the transparent electrode, causing the device to be damaged.

In order to overcome the problems described above, efforts have been made to replace the aluminum electrode with a high work-function metal to be used as an anode, and with transition metal oxides, such as vanadium oxide or tungsten oxide, being formed between the anode and the organic layer for transporting or injecting holes effectively so as to increase the power conversion efficiency. In addition, another transition metal oxide, zinc oxide, which is not corrosive to the transparent electrode, can be formed between the transparent electrode and the organic layer to be used as an electron-transporting or electron-injecting layer in place of PEDOT.

The transition metal oxide layers described above are usually formed by using a vacuum evaporation process, which is costly and difficult for producing a large-area device. Some transition metal oxide layers can be formed by the sol-gel method. While it is possible to produce a large-area device using the sol-gel method, the sol-gel method includes a high temperature annealing treatment. Consequently, the processing temperature is usually higher than the glass transition temperature (Tg) of the organic material, which may damage the organic layer.

### SUMMARY OF THE INVENTION

An object of the present invention is to provide optoelectronic devices and their forming methods, in which the devices have excellent efficiency and the methods are simple, speedy, cost-saved, and capable of producing the devices in low temperatures.

Accordingly, one embodiment of this invention provides an optoelectronic device, comprising; a first electrode; one or more first transition metal oxide layers, arranged on the first electrode; an active layer arranged on the one or more first transition metal oxide layers; one or more second transition metal oxide layers, arranged on the active layer, wherein the one or more second transition metal oxide layers comprise a nickel oxide (NiO) layer and/or a copper oxide (CuO) layer; and a second electrode, arranged on the one or more second transition metal oxide layers.

Accordingly, another embodiment of this invention provides an optoelectronic device, comprising: a first electrode; a transition metal oxide layer, arranged on the first electrode; an active layer, arranged on the transition metal oxide layer; a transition metal oxide mixing layer, arranged on the active layer, wherein the transition metal oxide mixing layer comprises two or more metal oxides comprising CuO and/or NiO mixed with at least an n-type transition metal oxide; and a second electrode arranged on the transition metal oxide mixing layer.

Accordingly, another embodiment of this invention provides a method for producing an optoelectronic device, comprising the steps of forming a first electrode; coating then drying one or more first solutions on the first electrode in sequence, thus forming one or more first transition metal oxide layers on the first electrode; coating then drying a second solution on the one or more first transition metal oxide layers, thus forming an active layer on the one or more first transition metal oxide layers; coating then drying one or more third solutions on the active layers in sequence, thus forming one or more second transition metal oxide layers on the active layer; and forming a second electrode on the one or more second transition metal oxide layers.

### BRIEF DESCRIPTION OF THE DRAWINGS

FIG. 1 is a sectional view showing an optoelectronic device according to a first embodiment of this invention.

FIG. 2 is a sectional view showing an optoelectronic device according to a second embodiment of this invention.

FIG. 3 is a sectional view showing an optoelectronic device according to a third embodiment of this invention.

FIG. 4 is a sectional view showing an optoelectronic device according to a fourth embodiment of this invention.

FIGS. 5-53 illustrate some organic solar cells produced by embodiments this invention.

FIG. 54 shows current-voltage characteristics of two organic solar cells produced by embodiments of the present invention, in which sample B has a structure as FIG. 16, sample A has a structure as sample B but without a NiO layer, and the characteristic charts are measured under 100 mA/cm².

FIG. 55 shows current-voltage characteristics of four organic solar cells produced by embodiments of the present invention, in which samples C, D, E, and F have a structure as FIG. 16 except that the concentrations of the NiO in the NiO solution are different, and the characteristic charts are measured under 100 mA/cm².

FIG. 56 shows long-term performances of sample A (FIG. 54) and sample C (FIG. 55).

### DESCRIPTION OF THE PREFERRED EMBODIMENT

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known components and process operations have not been described in detail in order not to unnecessarily obscure the present invention. While drawings are illustrated in detail, it is appreciated that the quantity of the disclosed components may be greater or less than that disclosed, except where expressly restricting the amount of the components.

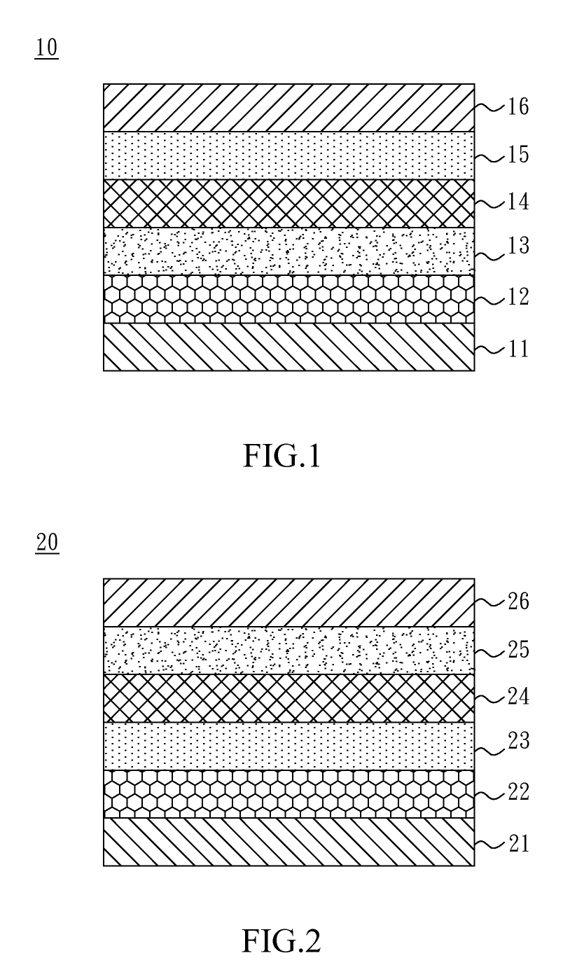

FIG. 1 is a sectional view showing optoelectronic device 10 according to a first embodiment of this invention. The optoelectronic device 10 at least includes: a transparent first electrode 12 arranged on a transparent substrate 11; one or more first transition metal oxide layers 13 arranged on the first electrode 12; an active layer 14 arranged on the one or more first transition metal oxide layers 13; one or more second transition metal oxide layers 15 arranged on the active layer 14, where the one or more second transition metal oxide layers 15 at least include a nickel oxide (NiO) layer and/or a copper oxide (CuO) layer; and a second electrode 16 arranged on the one or more second transition metal oxide layers 15.

FIG. 2 is a sectional view showing an optoelectronic device 20 according to a second embodiment of this invention. The optoelectronic device 20 at least includes: a transparent first electrode 22 arranged on a transparent substrate 21; one or more second transition metal oxide layers 23 arranged on the first electrode 22, where the one or more second transition metal oxide layers 23 at least include a nickel oxide (NiO) layer and/or a copper oxide (CuO) layer; an active layer 24 arranged on the one or more second transition metal oxide layers 23; one or more first transition metal oxide layers 25 arranged on the active layer 24; and a second electrode 26 arranged on the one or more first transition metal oxide layers 25.

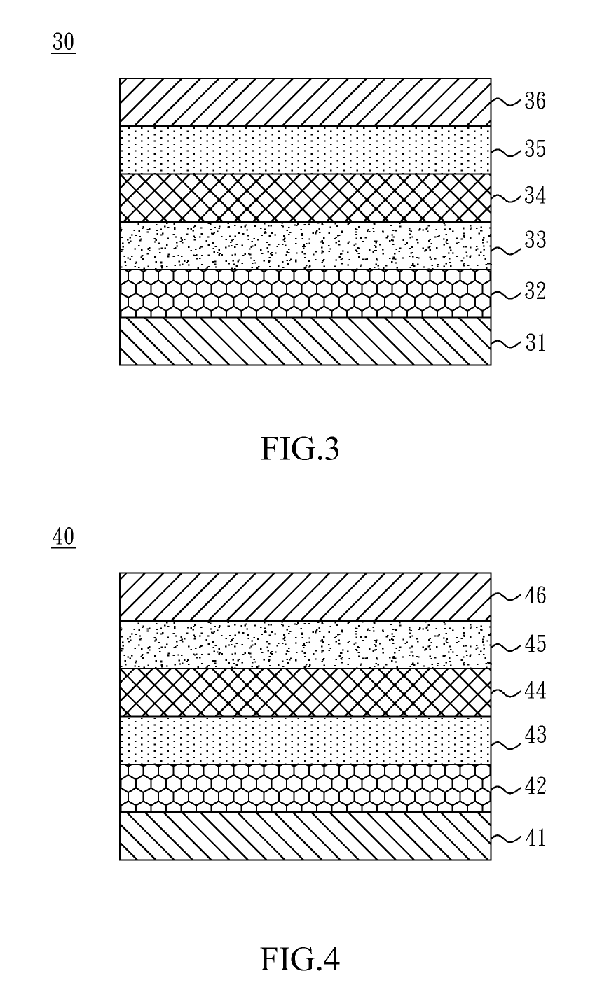

FIG. 3 is a sectional view showing an optoelectronic device 30 according to a third embodiment of this invention. The optoelectronic device 30 at least includes: a transparent first electrode 32 arranged on a transparent substrate 31; a transition metal oxide layer 33 arranged on the first electrode 32; an active layer 34 arranged on the transition metal oxide layer 33; a transition metal oxide mixing layer 35 arranged on the active layer 34, where the transition metal oxide mixing layer 35 is composed of at least two or more metal oxides comprising CuO and/or NiO mixed with at least an n-type transition metal oxide; and a second electrode 36 arranged on the transition metal oxide mixing layer 35.

FIG. 4 is a sectional view showing an optoelectronic device 40 according to a fourth embodiment of this invention. The optoelectronic device 40 at least includes: a transparent first electrode 42 arranged on a transparent substrate 41; a transition metal oxide mixing layer 43 arranged on the first electrode 42, where the transition metal oxide mixing layer 43 is composed of at least two or more metal oxides comprising CuO and/or NiO mixed with at least an n-type transition metal oxide; an active layer 44 arranged on the transition metal oxide mixing layer 43; a transition metal oxide layer 45 arranged on the active layer 44; and a second electrode 46 arranged on the transition metal oxide layer 45.

In embodiments shown in FIGS. 1-4, the active layer 14/24/34/44 is an organic layer employed as a light-emitting layer or a light-absorbing layer. In addition, the transparent substrate 11/21/31/41 is made essentially of glass or polymer, which is selected from a group consisting essentially of polyethylene teraphthalate (PET), polyethylene naphthalate (PEN), polycarbonate (PC), and combinations thereof. Alternatively, some embodiments of this invention may omit the transparent substrate 11/21/31/41. In addition, the second electrode 16/26/36/46 is preferably made of a metal such as aluminum, or a metal or alloy with high work-function, such as gold, silver, or composite materials. The first electrode 12/22/32/42 is made of a material selected from a group consisting essentially of indium tin oxide (ITO), indium zinc oxide (IZO), fluorine-doped tin oxide (FTO), a composite material with a sandwich structure, and combinations thereof, in which the composite material comprises a metal layer arranged between two zinc oxide layers, and the metal layer has a thickness between about 5 nm and about 10 nm and is selected from a group consisting essentially of silver, calcium, magnesium, aluminum, nickel, copper, gold, chromium, and combinations thereof. In addition, the first transition metal oxide layers 13/25 and the transition metal oxide layer 33/45 are preferably an n-type metal oxide semiconductor, which is made of zinc oxide or titanium oxide or other materials capable of transporting electrons or hindering holes. Notice that some embodiments of this invention may omit the first transition metal oxide layers 13/25 and the transition metal oxide layer 33/45. In addition, except nickel oxide and copper oxide, the above-mentioned one or more second transition metal oxide layers 15/23 and the transition metal oxide mixing layer 35/43 may comprise other materials capable of transporting holes or hindering electrons, for example, comprising an organic layer such as poly(3,4-ethylenedioxythiophene): polystyrene sulfonate), PEDOT:PSS, or comprising a material selected from a group consisting essentially of vanadium oxide, silver oxide, molybdenum oxide, tungsten oxide, carbon nanotube, and combinations thereof (combination of at least two of the foregoing elements in the group). In addition, the above-mentioned optoelectronic devices 10/20/30/40 are preferably a solar cell, but it may be a light-emitting diode or a light sensor. The polarity of the two electrodes of a solar cell depends on the material natures of its elements.

The 1^{st}, 2^{nd}, 3^{rd}, and 4^{th} embodiments are at least characterized in that the two electrodes, the active layer, and all the transition metal oxide layers can be formed by a solution process under a low temperature or room temperature, and the transition metal oxide layers comprising nickel oxide and/or copper oxide, as a buffer layer, can promote the efficiency of the devices. The detail to fabricate the two electrodes by using solution process is described in U.S. patent application Ser. No. 13/110,862, filed on May 18, 2011 and entitled “Method of Producing Conductive Thin Film,” the entire contents of which are incorporated herein by reference. Alternatively, conventional thermal evaporation or sputtering method may be employed to fabricate the two electrodes; however, the processing temperature should be controlled below 200° C.

An exemplary method for forming the active layer is described as follows. An organic solution is firstly coated on a surface prepared to form the active layer, for example, coated on the transition metal oxide layer 33 as shown in FIG. 3. Spin coating, jet printing, screen-printing, contact coating, dip coating, or roll-to-roll printing method may be used to coat the organic solution. The coated organic solution is then spontaneously or artificially dried with an elevated temperature that will not damage the organic solution, and later the active layer is formed.

As mentioned above, embodiments of this invention will employ a solution process to fabricate the transition metal oxide layers, including the one or more first transition metal oxide layers 13/25, the one or more second transition metal oxide layers 15/23, the transition metal oxide layer 33/45, and the transition metal oxide mixing layer 35/43. The solution process may comprises a “micro/nano particle stacking method or a sol-gel method; the former is preferred. The following example describes how to fabricate a nickel oxide layer, i.e., a transition metal oxide layer, by using the micro/nano particle stacking method. Several milligrams of nickel oxide powders are firstly weighted then placed into several milliliters of a solvent in a container, thus forming a nickel oxide solution, i.e., a transition metal oxide solution, whose concentration is between about 0.01 mg/ml and about 100 mg/ml. Moreover, the morphology of the nickel oxide powders or other micro/nano transition metal oxide powders may comprise micro/nano particle, micro/nano island, micro/nano rod, micro/nano wire, micro/nano tube, micro/nano porous structure, and combinations thereof. Ultrasonic waves then vibrate the nickel oxide solution for about tens of minutes to several hours, such that the nickel oxide powders are well dissolved or suspended in the solution. After vibration, one of the foregoing coating methods is employed to coat the nickel oxide solution on a surface prepared to form the nickel oxide layer. The nickel oxide solution is then spontaneously or artificially dried, thus forming the nickel oxide layer. Similarly, the steps described in this example can form other transition metal oxide layers.

Typically, the solvent of the transition metal oxide solution may be water or general organic solvents; however, if the transition metal oxide layer will be formed on the active layer, the dielectric constant of the solvent should be considered. Taking the embodiment shown in FIG. 1 as an example, if the active layer 14 is P3HT:PCBM with a dielectric constant about 3, and the lowest one of the one or more second transition metal oxide layers 15, i.e., the one contacted with the active layer 14, is a copper oxide layer, then the solvent of the copper oxide solution may select isopropanol (IPA) with a dielectric constant about 18, so as to prevent the solvent from dissolving or damaging the active layer 14. In other words, the difference of the dielectric constant between the solvent and the active layer should be sufficient to prevent the active layer from being damaged.

The micro/nano particle stacking method has advantages including low cost, capability of fabricating large area formation, and speedy process. By this method, a single transition metal oxide layer can be formed within a minute. In contrast, the thermal evaporation is costly and time-consumed. Moreover, the crystal structure of the transition metal oxide layer formed by this method is amorphous, and an annealing step is needed to make it crystalline. However, the annealing step may damage the active layer, and the selectivity of the substrate is therefore limited. For example, it cannot select a plastic substrate due to the annealing temperature. The micro/nano particle stacking method coats a solution comprising micro/nano transition metal oxide structures on a surface, and then the structures are stacked to form a transition metal oxide layer. Depending on the morphology of the structures, the formed transition metal oxide layer can be single crystalline, polycrystalline, or amorphous. Therefore, the micro/nano particle stacking method needs not an annealing step and will not damage the active layer. The selectivity of the substrate is hence broadened.

In addition, the micro/nano particle stacking method is used to fabricate the transition metal oxide mixing layer 35/43, which comprises nickel oxide and/or copper oxide, and at least an n-type transition metal oxide, and the weight ratio of the elements can be easily adjusted to optimize the efficiency of the devices. In contrast, because metal oxides have different boiling points, conventional co-evaporation method is difficult to fabricate a transition metal oxide mixing layer, particularly with a specific weight ratio of the elements. In addition, it may generate unwanted metal oxide alloys during fabrication.

Additional description regarding the micro/nano particle stacking method may refer to U.S. application Ser. No. 12/574,697, filed on Oct. 6, 2009 and entitled “Suspension or Solution for Organic Optoelectronic Device, Making Method thereof, and Applications,” the entire contents of which are incorporated herein by reference.

As mentioned above, the sol-gel method may be used as well to produce the transition metal oxide layers. The first is to prepare a transition metal oxide sol-gel solution, which comprises reactants or precursors (as solute) of the transition metal oxide and a solvent, and the concentration of the solute is between about 0.01 M and about 10 M. One of the foregoing coating methods is used to coat the sol-gel solution on a surface that prepared to form the transition metal oxide layer. After that, a temperature below 140° C. is used to heat the sol-gel solution, thus forming a transition metal oxide layer. Experiments show that the concentration of the solute should be determined according to the material of other layers, such as the active layer.

The following example describes using the sol-gel method to produce a copper oxide layer. The first is to prepare a copper oxide sol-gel solution comprising Cu(CH₃COO)₂H₂O, monoethanolamine (MBA), deionized water, and isopropanol (IPA). The concentration of Cu(CH₃COO)₂H₂O may be 0.025 M, 2.5 M, or 8 M according various situations. The copper oxide sol-gel solution is coated then heated by a temperature between about 100° C. and about 130° C., thus forming the copper oxide layer.

### Examples

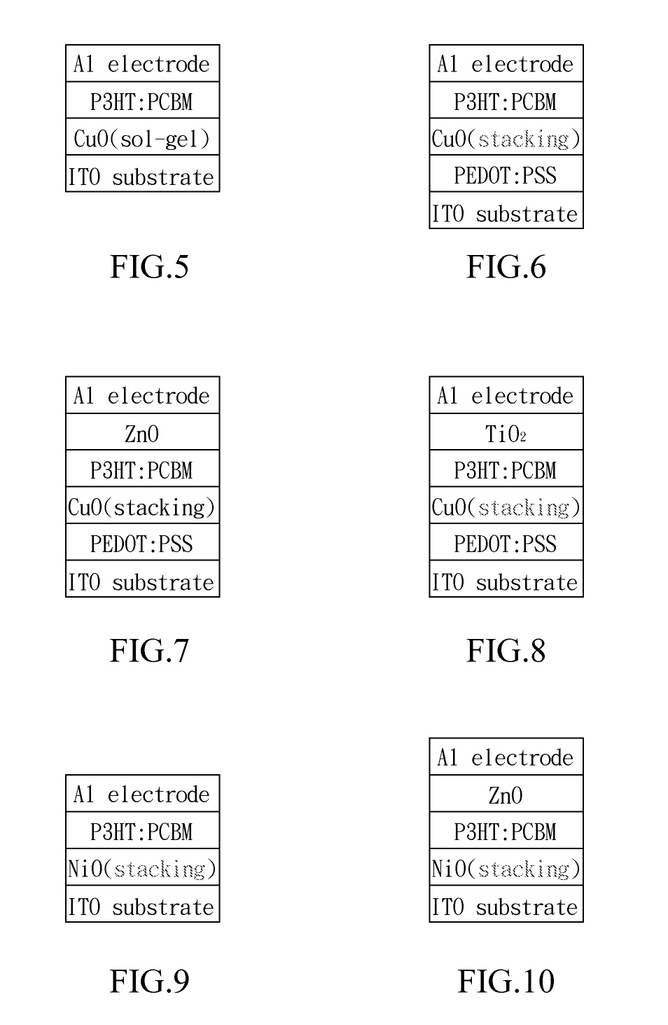

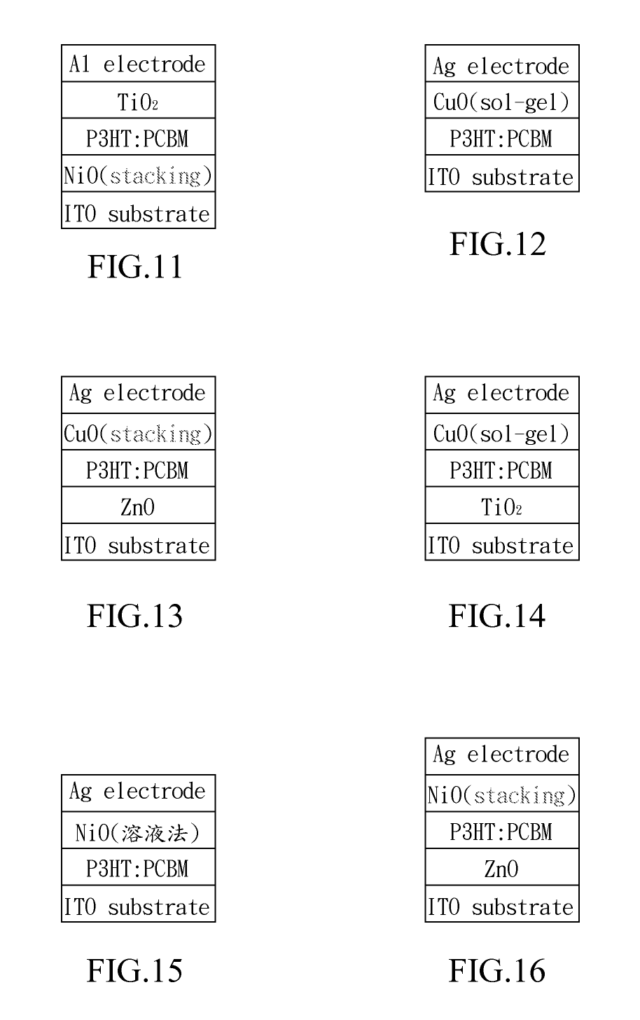

FIGS. 5-11 illustrate some exemplary organic solar cells having a structure as shown in FIG. 2, in which P3HT:PCBM is the active layer, Al electrode is the negative electrode, and ITO (indium tin oxide) substrate is the positive electrode. The note “stacking” in parentheses indicates that the structure is formed by the micro/nano particle stacking method. The note “sol-gel” in parentheses indicates that the structure is formed by the sol-gel method. In addition, copper oxide (CuO) and PEDOT:PSS are hole-transporting layers, and zinc oxide (ZnO) and titanium oxide (TiO₂) are electron-transporting layers.

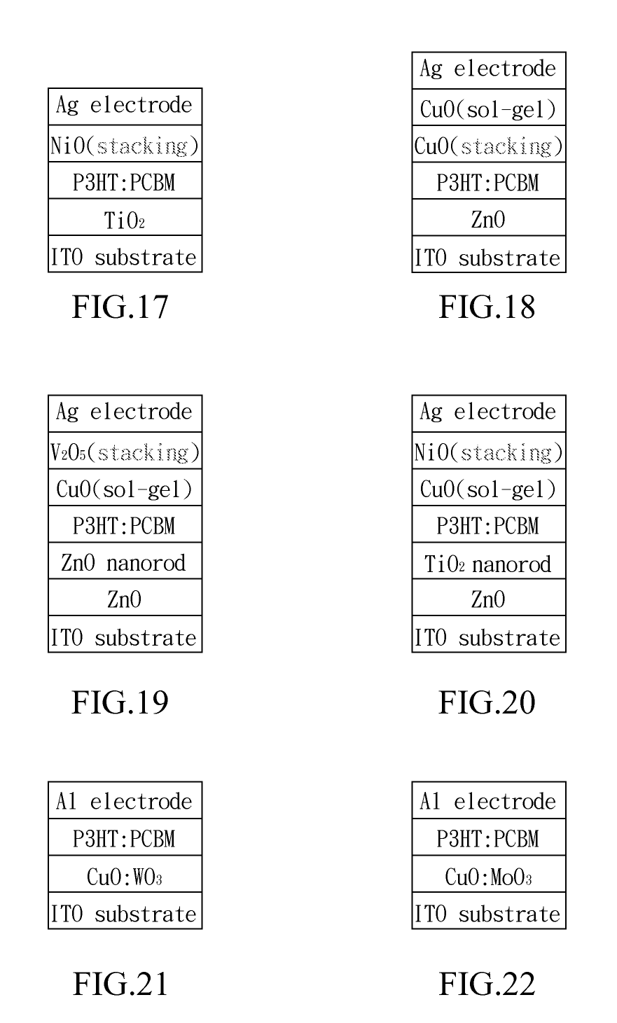

FIGS. 12-20 illustrate some exemplary organic solar cells having a structure as shown in FIG. 1, in which P3HT:PCBM is the active layer, Ag electrode is the positive electrode, and ITO substrate is the negative electrode. The solar cells shown in FIGS. 19 and 20 have two second transition metal oxide layers and two first transition metal oxide layers.

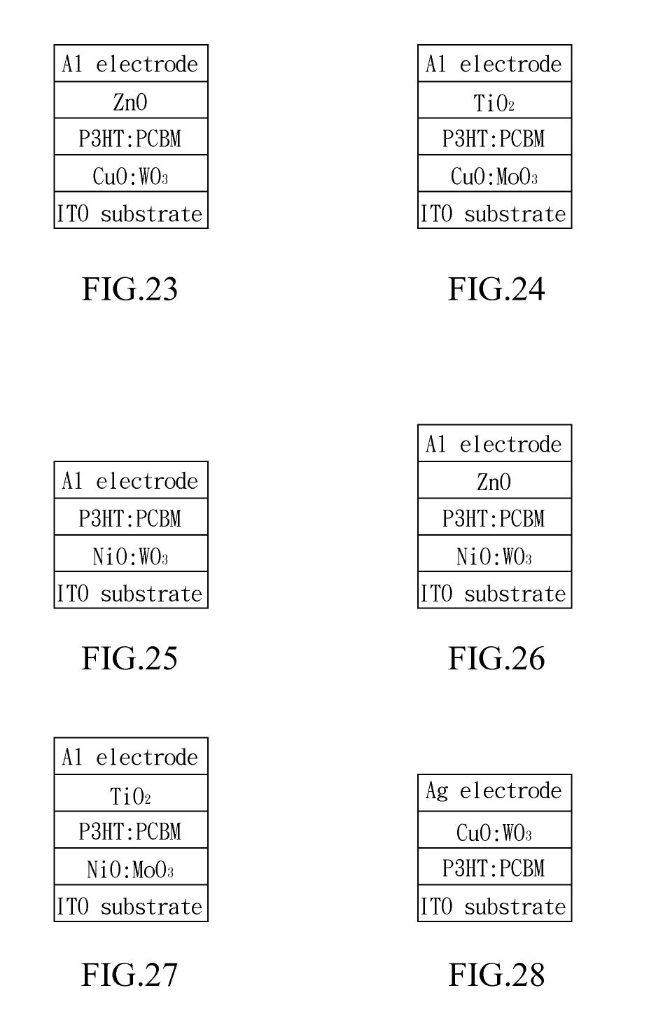

FIGS. 21-27 illustrate some exemplary organic solar cells having a structure as shown in FIG. 4, in which P3HT:PCBM is the active layer, Al electrode is the negative electrode, and ITO substrate is the positive electrode. CuO:WO₃ indicates a transition metal oxide mixing layer, copper oxide mixed with tungsten oxide; similarly, CuO:MoO₃ indicates copper oxide mixed with molybdenum oxide.

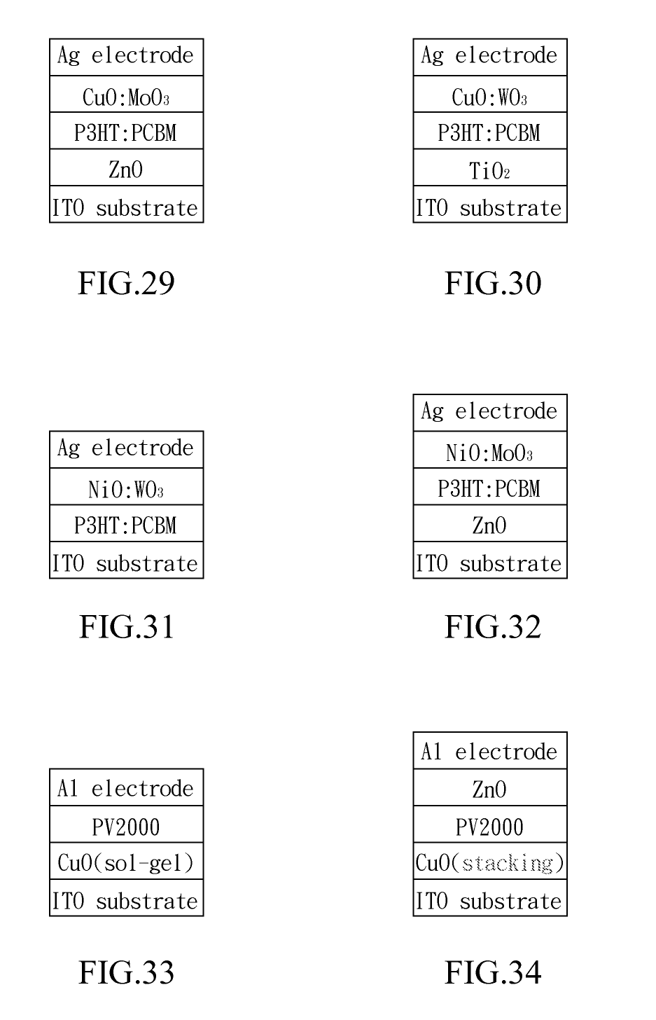

FIGS. 28-32 illustrate some exemplary organic solar cells having a structure as shown in FIG. 3, in which P3HT:PCBM is the active layer, Ag electrode is the positive electrode, and ITO substrate is the negative electrode.

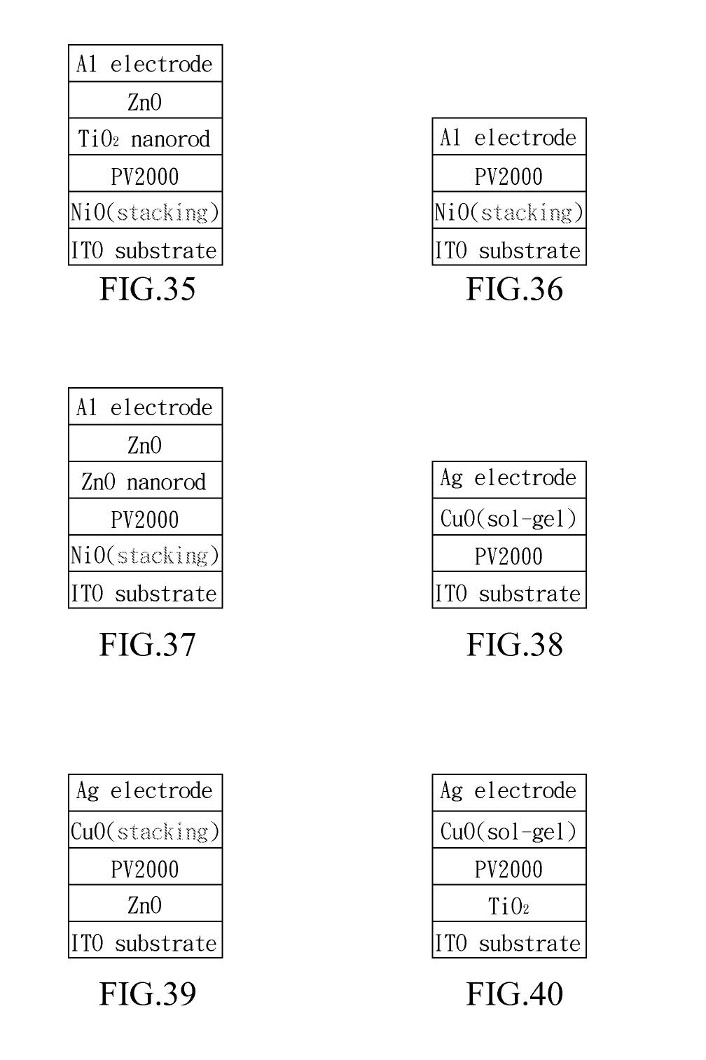

FIGS. 33-37 illustrate some exemplary organic solar cells having a structure as shown in FIG. 2, in which PV2000(P3HT:ICBA) is the active layer, Al electrode is the negative electrode, and ITO substrate is the positive electrode.

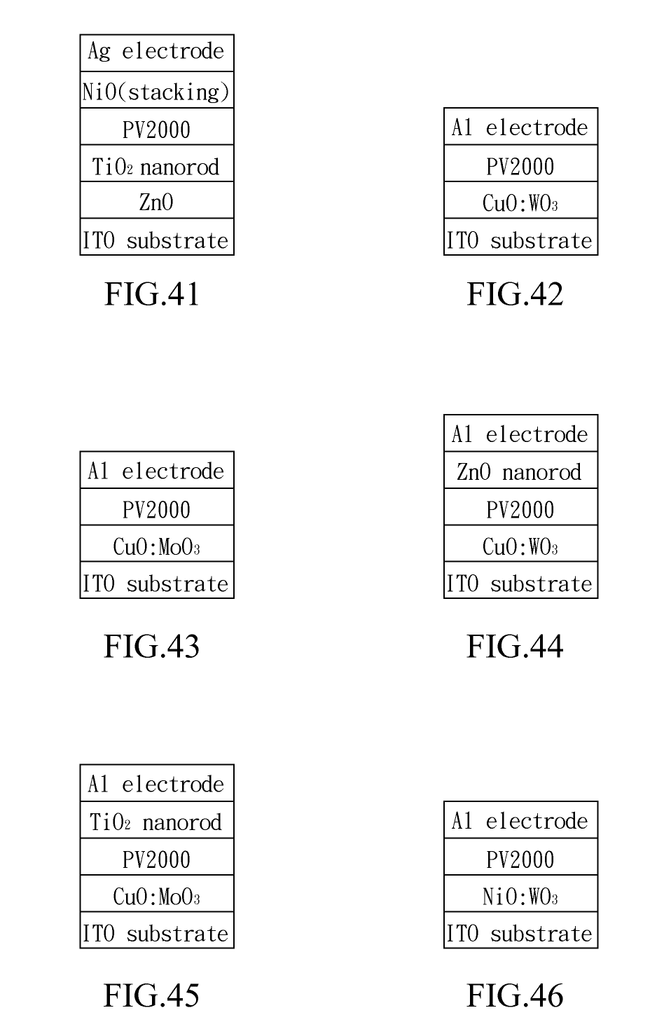

FIGS. 38-41 illustrate some exemplary organic solar cells having a structure as shown in FIG. 1, in which PV2000(P3HT:ICBA) is the active layer, Ag electrode is the positive electrode, and ITO substrate is the negative electrode.

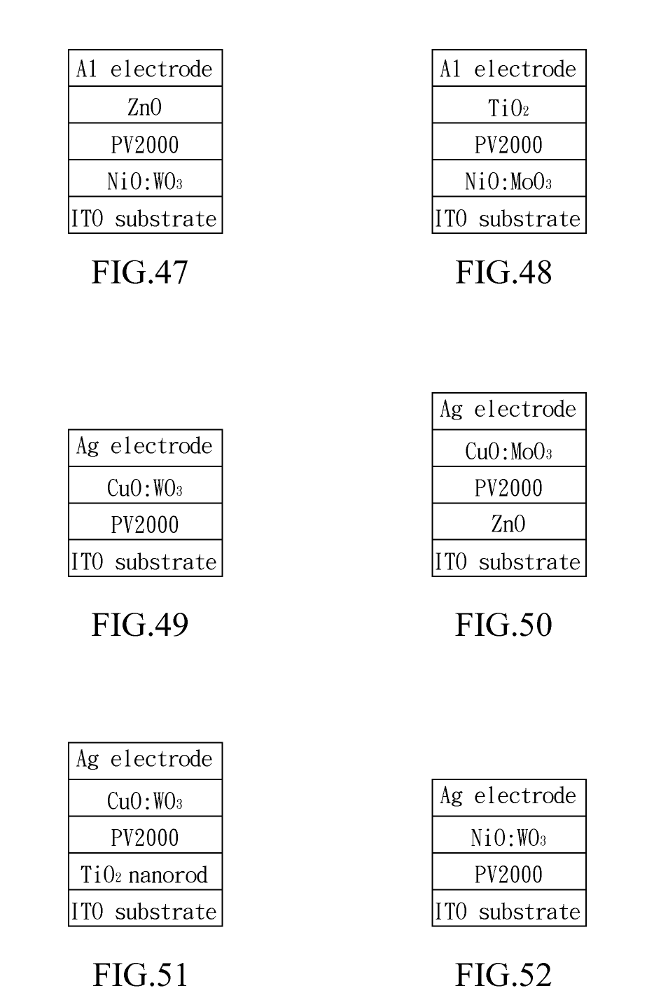

FIGS. 42-48 illustrate some exemplary organic solar cells having a structure as shown in FIG. 4, in which PV2000(P3HT:ICBA) is the active layer, Al electrode is the negative electrode, and ITO substrate is the positive electrode.

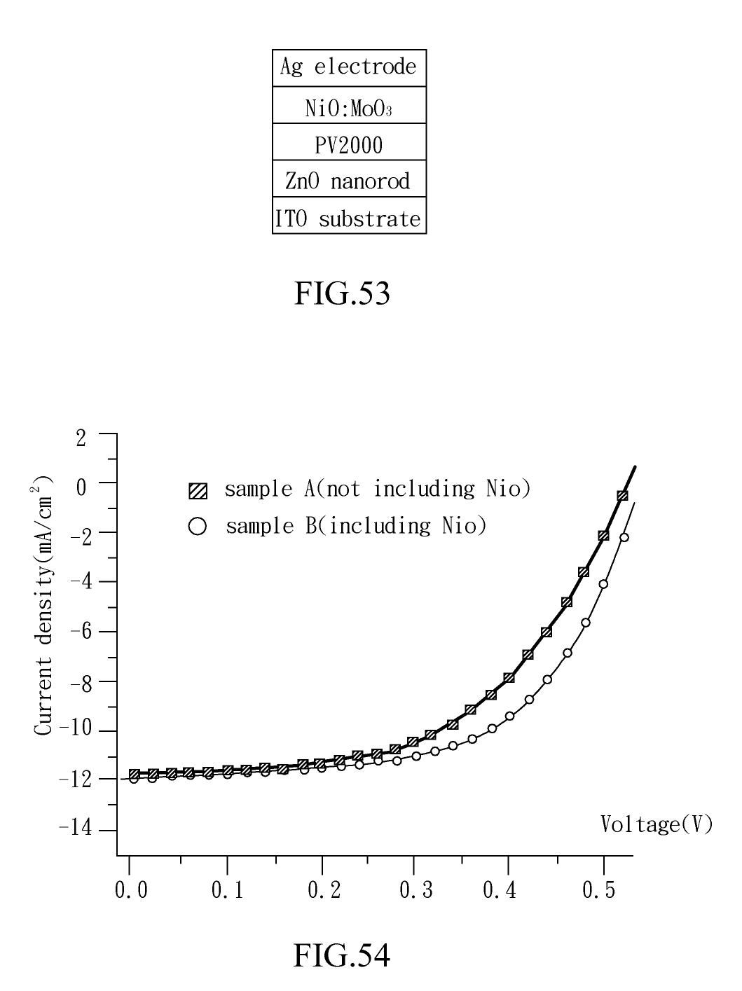

FIGS. 49-53 illustrate some exemplary organic solar cells having a structure as shown in FIG. 3, in which PV2000(P3HT:ICBA) is the active layer, Ag electrode is the positive electrode, and ITO substrate is the negative electrode.

FIG. 54 shows current-voltage characteristics of two organic solar cells produced by embodiments of the present invention, in which sample B has a structure as FIG. 16, sample A has a structure as sample B but without a NiO layer, and the characteristic charts are measured under 100 mA/cm². The results show that the fill factor of sample B is higher than sample A due to decreased current leakage by the nickel oxide buffer layer.

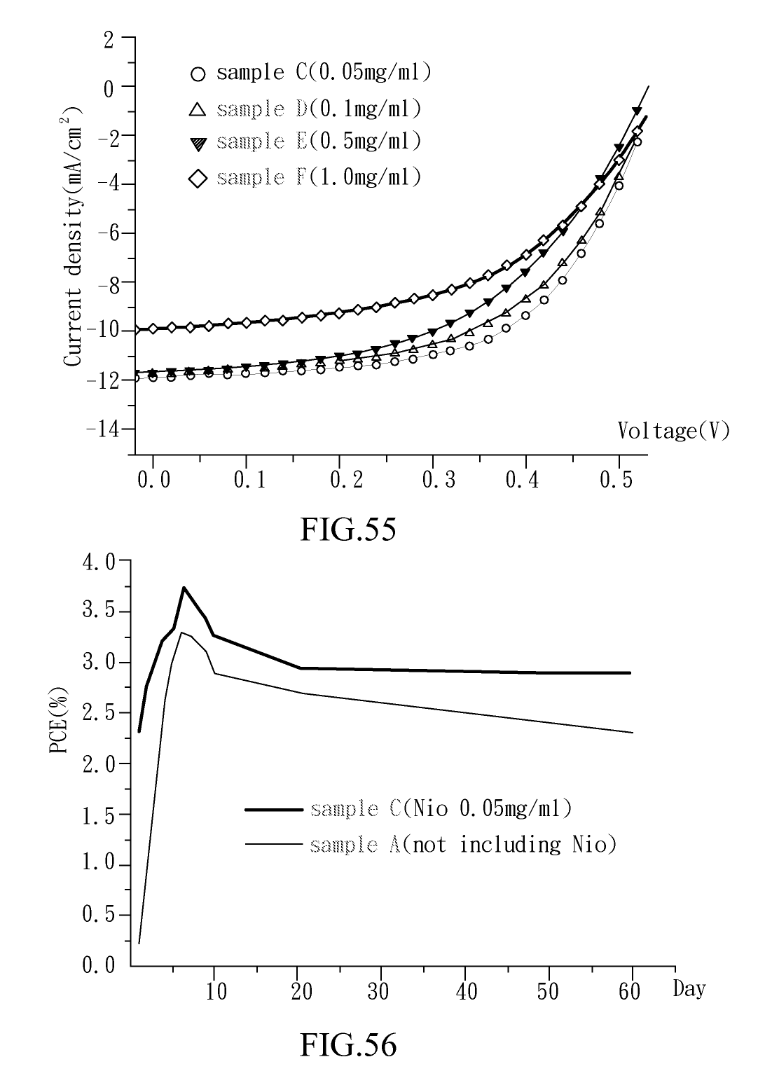

Experiment show that when using the micro/nano particle stacking method to form the transition metal oxide layers, the concentration of the transition metal oxide solution will affect the thickness of the transition metal oxide layer and the performance of the device. FIG. 55 shows current-voltage characteristics of four organic solar cells produced by embodiments of the present invention, in which samples C, D, E, and F have a structure as FIG. 16 except that the concentrations of the NiO in the NiO solution are different, and the characteristic charts are measured under 100 mA/cm². The results show that sample C has the maximum fill factor, sample D and F are next, and sample F has minimum one. Because sample C has the thinnest thickness of the NiO layer, it has better carrier mobility than others.

FIG. 56 shows long-term performances of sample A (FIG. 54) and sample C (FIG. 55). Sample A and sample C are placed in air without encapsulation to investigate their long-term performance. The results show that after being placed in air for 1000 hours, the efficiency of sample C decreases to 90% of the highest efficiency, decreasing about 10% amount. After being placed in air for 1000 hours, the efficiency of sample A decreases to 60% of the highest efficiency, decreasing; about 40% amount.

The results show that the transition metal oxide layers of this invention can effectively prevent moisture and oxygen from entering the device, and thus can promote the reliability of the device. Additional experiments show that the long-term performances are better if the devices are roughly encapsulated. This indicates that a well, costly encapsulation may be unnecessary for the optoelectronic devices of this invention, thereby saving the cost.

Notice that in this context the term “micro/nano” refers to “micro or nano” or “micro and nano,” and the term “and/or” refers to “and” or “or.”

Although specific embodiments have been illustrated and described, it will be appreciated by those skilled in the art that various modifications may be made without departing from the scope of the present invention, which is intended to be limited solely by the appended claims.

What is claimed is:

1. An optoelectronic device, comprising:
a first electrode;
one or more first transition metal oxide layers, arranged on the first electrode;
an active layer arranged on the one or more first transition metal oxide layers;
one or more second transition metal oxide layers, arranged on the active layer, wherein the one or more second transition metal oxide layers comprise a nickel oxide (NiO) layer and/or a copper oxide (CuO) layer; and
a second electrode, arranged on the one or more second transition metal oxide layers.

2. The optoelectronic device as recited in claim 1, wherein the active layer comprises an organic layer employed as a light-emitting layer or a light-absorbing layer.

3. The optoelectronic device as recited in claim 1, further comprising a transparent substrate arranged below the first electrode or arranged above the second electrode, wherein the transparent substrate is made essentially of a glass or a polymer.

4. The optoelectronic device as recited in claim 3, wherein the polymer is selected from a group consisting essentially of polyethylene teraphthalate (PET), polyethylene naphthalate (PEN), polycarbonate (PC), and combinations thereof.

5. The optoelectronic device as recited in claim 1, wherein one of the first electrode and the second electrode is a transparent electrode, and the other one is a metal electrode, and wherein the transparent electrode is made of a material selected from a group consisting essentially of indium tin oxide (ITO), indium zinc oxide (IZO), fluorine-doped tin oxide (FTO), a composite material with a sandwich structure, and combinations thereof, in which the composite material comprises a metal layer arranged between two zinc oxide layers.

6. The optoelectronic device as recited in claim 5, wherein the metal layer is selected from a group consisting essentially of silver, calcium, magnesium, aluminum, nickel, copper, gold, chromium, and combinations thereof.

7. The optoelectronic device as recited in claim 5, wherein the thickness of the metal layer is between about 5 nm and about 10 nm.

8. The optoelectronic device as recited in claim 1, wherein the one or more first transition metal oxide layers comprise an n-type metal oxide semiconductor, which is made essentially of zinc oxide or titanium oxide.

9. The optoelectronic device as recited in claim 1, wherein the crystal structure of the one or more first transition metal oxide layers and the one or more second transition metal oxide layers comprises single crystalline, polycrystalline, or amorphous.

10. The optoelectronic device as recited in claim 1, wherein the one or more first transition metal oxide layers and the one or more second transition metal oxide layers comprise stacked micro/nano structures selected from micro/nano particle, micro/nano island, micro/nano rod, micro/nano wire, micro/nano tube, micro/nano porous structure, and combinations thereof.

11. The optoelectronic device as recited in claim 1, further comprising an organic layer arranged between the first electrode and the active layer.

12. The optoelectronic device as recited in claim 1, wherein the optoelectronic device is a solar cell, a light-emitting diode, or a light sensor.

13. An optoelectronic device, comprising:
a first electrode;
a transition metal oxide layer, arranged on the first electrode;
an active layer, arranged on the transition metal oxide layer;
a transition metal oxide mixing layer, arranged on the active layer, wherein the transition metal oxide mixing layer comprises two or more metal oxides comprising CuO and/or NiO mixed with at least an n-type transition metal oxide; and
a second electrode arranged on the transition metal oxide mixing layer.

14. The optoelectronic device as recited in claim 13, wherein the active layer comprises an organic layer employed as a light-emitting layer or a light-absorbing layer.

15. The optoelectronic device as recited in claim 13, further comprising a transparent substrate arranged below the first electrode or arranged above the second electrode, wherein the transparent substrate is made essentially of a glass or a polymer.

16. The optoelectronic device as recited in claim 15, wherein the polymer is selected from a group consisting essentially of polyethylene teraphthalate (PET), polyethylene naphthalate (PEN), polycarbonate (PC), and combinations thereof.

17. The optoelectronic device as recited in claim 13, wherein one of the first electrode and the second electrode is a transparent electrode, and the other one is a metal electrode, and wherein the transparent electrode is made of a material selected from a group consisting essentially of indium tin oxide (ITO), indium zinc oxide (IZO), fluorine-doped tin oxide (FTO), a composite material with a sandwich structure, and combinations thereof, in which the composite material comprises a metal layer arranged between two zinc oxide layers.

18. The optoelectronic device as recited in claim 17, wherein the metal layer is selected from a group consisting essentially of silver, calcium, magnesium, aluminum, nickel, copper, gold, chromium, and combinations thereof.

19. The optoelectronic device as recited in claim 17, wherein the thickness of the metal layer is between about 5 nm and about 10 nm.

20. The optoelectronic device as recited in claim 13, wherein the transition metal oxide layer comprises an n-type metal oxide semiconductor, which is made essentially of zinc oxide or titanium oxide.

21. The optoelectronic device as recited in claim 13, wherein the crystal structure of the transition metal oxide layer and the transition metal oxide mixing layer comprises single crystalline, polycrystalline, or amorphous.

22. The optoelectronic device as recited in claim 13, wherein the transition metal oxide layer and the transition metal oxide mixing layer comprise stacked micro/nano structures selected from micro/nano particle, micro/nano island, micro/nano rod, micro/nano wire, micro/nano tube, micro/nano porous structure, and combinations thereof.

23. The optoelectronic device as recited in claim 13, wherein the optoelectronic device is a solar cell, a light-emitting diode, or a light sensor.

24. The optoelectronic device as recited in claim 13, wherein the n-type transition metal oxide comprises tungsten oxide (WO₃) or molybdenum oxide (MoO₃).

25. The optoelectronic device as recited in claim 13, further comprising an organic layer arranged between the first electrode and the active layer.

26. A method for producing an optoelectronic device, comprising the steps of
forming a first electrode;
coating then drying one or more first solutions on the first electrode in sequence, thus forming one or more first transition metal oxide layers on the first electrode;
coating then drying a second solution on the one or more first transition metal oxide layers, thus forming an active layer on the one or more first transition metal oxide layers;
coating then drying one or more third solutions on the active layers in sequence, thus forming one or more second transition metal oxide layers on the active layer; and
forming a second electrode on the one or more second transition metal oxide layers.

27. The method as recited in claim 26, wherein one of the third solutions comprises nickel oxide or copper oxide, or two of the third solutions respectively comprise nickel oxide and copper oxide.

28. The method as recited in claim 26, wherein the third solutions comprise two or more metal oxides comprising CuO and/or NiO mixed with at least an n-type transition metal oxide.

29. The method as recited in claim 26, wherein the first solutions and the third solutions comprise a solvent and a plurality of micro/nano transition metal oxide structures, which are stacked to form the first transition metal oxide layers and the second transition metal oxide layers.

30. The method as recited in claim 29, wherein the micro/nano transition metal oxide structures are selected from micro/nano particle, micro/nano island, micro/nano rod, micro/nano wire, micro/nano tube, micro/nano porous structure, and combinations thereof.

31. The method as recited in claim 29, wherein one of the first solutions or one of the third solutions contacts with the active layer, and the difference between the dielectric constant of the solvent and the dielectric constant of the active layer is sufficient to prevent the active layer from being damaged.

32. The method as recited in claim 26, wherein the first solutions and the third solutions comprise a sol-gel solution including a solvent and reactants or precursors of transition metal oxides as a solute having a concentration between about 0.01 M and about 10 M, and the sol-gel solution is heated to form the first transition metal oxide layers and the second transition metal oxide layers.

33. The method as recited in claim 26, wherein the temperatures for drying the first solutions are room temperature or below about 200° C., the temperature for drying the second solution is room temperature, and the temperatures for drying the third solutions are room temperature or below about 130° C.

34. The method as recited in claim 26, wherein the steps are performed in a reverse order.

35. The method as recited in claim 34, wherein the first solutions comprise a solvent, the difference between the dielectric constant of the solvent and the dielectric constant of the active layer is sufficient to prevent the active layer from being damaged.

36. The method as recited in claim 26, wherein the crystal structure of the first transition metal oxide layers and the second transition metal oxide layers comprises single crystalline, polycrystalline, or amorphous.

37. The method as recited in claim 26, wherein the first solutions, the second solution, and the third solutions are coated by spin coating, jet printing, screen-printing, contact coating, dip coating, or roll-to-roll printing method.

38. The method as recited in claim 26, further comprising forming; an organic layer between the first electrode and the active layer.
